(19) United States
(12) Patent Application Publication
(10) Pub. No.: US 2026/0304791 A1
(43) Pub. Date: Oct. 1, 2026

(54) MEMORY-ONLY CUBES AND METHODS OF FORMING THE SAME

(71) Applicant: Micron Technology, Inc., Boise, ID (US)

(72) Inventor: Wei Zhou, Boise, ID (US)

(21) Appl. No.: 19/561,508

(22) Filed: Mar. 10, 2026

Related U.S. Application Data
(60) Provisional application No. 63/781,970, filed on Apr. 1, 2025.

(51) Int. Cl. H10B 80/00; H10W 72/00; H10W 80/00; H10W 90/00; H10W 90/20; H10W 90/26

(52) U.S. Cl. CPC H10B 80/00; H10W 72/0198; H10W 80/312; H10W 90/26; H10W 90/291; H10W 90/297; H10W 90/724; H10W 90/792

(57) ABSTRACT

Memory-only cubes and methods of forming the same are disclosed herein. In one embodiment, a semiconductor device includes a stack of semiconductor dies including a first semiconductor die and a second semiconductor die bonded to the first semiconductor die. A dielectric layer can be disposed on a side of the first semiconductor die opposite the second semiconductor die and can include a plurality of interconnect structures formed therein. The semiconductor device can lack a bondline between the first semiconductor die and the dielectric layer. The dielectric layer can comprise low-temperature silicon dioxide. One or more of the plurality of interconnect structures can extend at least partway through the dielectric layer. The semiconductor device can include external contacts formed on the interconnect structures. The dielectric layer can emulate an interface die or logic die of a high-bandwidth memory device.

### CROSS-REFERENCE TO RELATED APPLICATION(S)

The present application claims priority to U.S. Provisional Patent Application No. 63/781,970, filed Apr. 1, 2025, the disclosure of which is incorporated herein by reference in its entirety.

### TECHNICAL FIELD

The present disclosure relates generally to semiconductor devices. For example, several embodiments of the present technology described in detail below are directed to memory cubes that are formed without use of an interface wafer or die, and to methods of assembling the same.

### BACKGROUND

Semiconductor devices are commonly arranged in vertical stacks. For example, memory cubes, particularly in the context of high-bandwidth memory (HBM) devices, typically involve the integration of multiple memory dies stacked vertically to form compact, high-performance memory modules. These memory cubes are often used in conjunction with a host device within system-in-package (SiP) configurations to enhance data processing speeds and reduce physical space requirements.

Memory cubes traditionally utilize interface dies, often logic dies, that facilitate communication between the memory dies and external devices, such as host devices. The interface dies typically contain through-silicon vias (TSVs) and other interconnect structures that provide necessary pathways for electrical signals between the stacked memory dies and the host devices or other external circuitry. Use of interface dies, however, can introduce additional complexity and cost in the manufacturing process, and can limit reducing the overall heights of the memory cubes.

### BRIEF DESCRIPTION OF THE DRAWINGS

Many aspects of the present disclosure can be better understood with reference to the following drawings. The components in the drawings are not necessarily to scale. Instead, emphasis is placed on illustrating clearly the principles of the present disclosure. The drawings should not be taken to limit the disclosure to the specific embodiments shown, but are provided for explanation and understanding.

FIG. 1 illustrates a cross-sectional side view of a semiconductor device configured in accordance with various embodiments of the present technology.

FIG. 2 illustrates a cross-sectional side view of a system-in-package (SiP) device that implements a semiconductor device configured in accordance with various embodiments of the present technology.

FIG. 3 illustrates a cross-sectional side view of another system-in-package that implements a semiconductor device configured in accordance with various embodiments of the present technology.

FIG. 4 is a flow diagram illustrating a method of manufacturing a semiconductor device in accordance with various embodiments of the present technology.

FIG. 5A illustrates a cross-sectional side view of a temporary carrier substrate configured in accordance with various embodiments of the present technology.

FIGS. 5B-5E illustrate cross-sectional side views of a semiconductor device at various stages of manufacturing in accordance with various embodiments of the present technology.

FIG. 6 illustrates a cross-sectional side view of a temporary carrier substrate configured in accordance with various embodiments of the present technology.

FIG. 7 illustrates a cross-sectional side view of a temporary carrier substrate configured in accordance with various embodiments of the present technology.

FIG. 8 illustrates a block diagram of a device assembly within a system configured in accordance with various embodiments of the present technology.

### DETAILED DESCRIPTION

The present technology relates generally to semiconductor devices (e.g., memory cubes) that are formed without interface dies or interface wafers. For example, several embodiments of the present technology described in greater detail below are directed to memory cubes that include stacks of memory dies positioned on or over dielectric layers. Vias and/or other interconnect structures can be formed in the dielectric layer to facilitate communicably coupling the memory dies to host devices and other external circuitry. Thus, the dielectric layers can be used in lieu of interface dies or wafers. In some embodiments, the dielectric layers can be formed of silicon dioxide (SiO2), such as low-temperature SiO2, or other suitable materials. It is expected that such memory cubes and methods of assembling the same can result in thinner and/or more cost-effective memory modules that perform similarly to traditional high-bandwidth memory.

In the following description, specific details are set forth to provide a thorough understanding of aspects of the present technology. One skilled in the relevant art will recognize, however, that the systems, devices, and techniques described herein can be practiced without one or more of the specific details set forth herein, or with other methods, components, materials, etc. For example, although primarily described below in the context of memory cubes that implements stacks of dynamic random-access memory (DRAM) dies, the present technology is not so limited. Other embodiments of the present technology can be directed to memory cubes that implement stacks of other forms of volatile memory dies, stacks of non-volatile memory dies (e.g., NOT-AND (NAND) memory dies), and/or stacks that include both volatile and non-volatile memory dies.

Reference throughout this specification to an “example” or an “embodiment” means that a particular feature, structure, or characteristic described in connection with the example or embodiment is included in at least one example or embodiment of the present technology. Thus, use of the phrases “for example,” “as an example,” or “an embodiment” herein are not necessarily all referring to the same example or embodiment and are not necessarily limited to the specific example or embodiment discussed. Furthermore, features, structures, or characteristics of the present technology described herein may be combined in any suitable manner to provide further examples or embodiments of the present technology.

Spatially relative terms (e.g., “beneath,” “below,” “over,” “under,” “above,” “upper,” “top,” “bottom,” “left,” “right,” “center,” “middle,” and the like) may be used herein for ease of description to describe one element's or feature's relationship relative to one or more other elements or features as illustrated in the figures. It will be understood that the spatially relative terms are intended to encompass different orientations of a device or system in use or operation, in addition to the orientation depicted in the figures. For example, if a device or system illustrated in the figures is rotated, turned, or flipped about a horizontal axis, elements or features described as “below” or “beneath” or “under” one or more other elements or features may then be oriented “above” the one or more other elements or features. Thus, the exemplary terms “below” and “under” are non-limiting and can encompass both an orientation of above and below. The device or system may additionally, or alternatively, be otherwise oriented (e.g., rotated ninety degrees about a vertical axis, or at other orientations) than illustrated in the figures, and the spatially relative descriptors used herein are interpreted accordingly. In addition, it will also be understood that when an element is referred to as being “between” two other elements, it can be the only element between the two other elements, or one or more intervening elements may also be present.

### A. Selected Embodiments of Memory-Only Cubes, and Associated Systems, Devices, and Methods

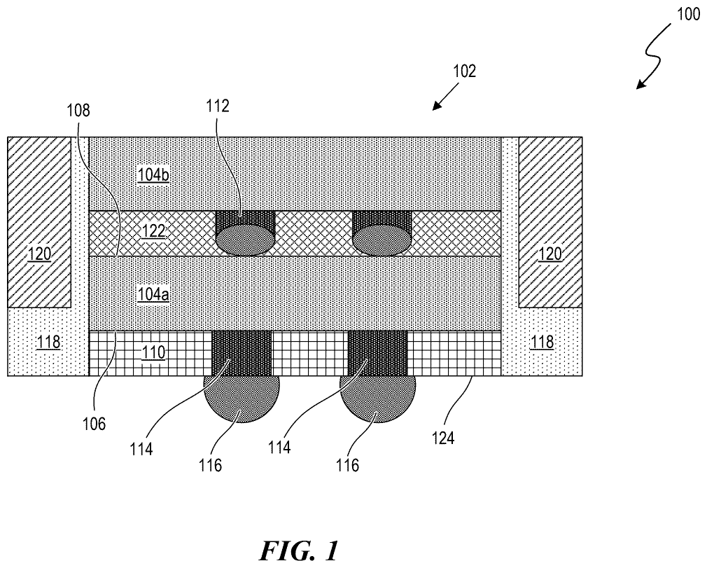

FIG. 1 illustrates a cross-sectional side view of a semiconductor device 100 configured in accordance with various embodiments of the present technology. As shown, the semiconductor device 100 includes a stack 102 of semiconductor dies 104 (identified individually in FIG. 1 as semiconductor die 104a and semiconductor die 104b), a dielectric layer 110, a gapfill material 118, and a molding compound 120.

In some embodiments, the semiconductor dies 104 can be memory dies. For example, all or a subset of the semiconductor dies 104 can be volatile memory dies. As a specific example, the semiconductor dies 104a and 104b can be DRAM memory dies. In other embodiments, one or more of the semiconductor dies 104 can be non-volatile memory dies. In embodiments in which all or a subset of the semiconductor dies are memory dies, the semiconductor device 100 can be referred to as a “memory cube” or “memory module.” Although shown with only two semiconductor dies 104 in FIG. 1, semiconductor devices configured in accordance with other embodiments of the present technology can include more than two semiconductor dies arranged in a stack and/or more than one stack of semiconductor dies.

The semiconductor dies 104 can be arranged front-to-back, back-to-front, front-to-front, and/or back-to-back in the stack 102. For example, the semiconductor dies 104a can include a first side 106 and a second side 108 opposite the first side 106. In some embodiments, the first side 106 can be a front side of the semiconductor die 104a, and the second side 108 can be a back side of the semiconductor die 104a. In these embodiments, a front side or a back side of the semiconductor die 104b can be attached to the second side 108 of the semiconductor die 104a. In other embodiments, the first side 106 can be a back side of the semiconductor die 104a, and the second side 108 can be a back side of the semiconductor die 104a. In these embodiments, a front side or a back side of the semiconductor die 104b can be attached to the second side 108 of the semiconductor die 104a.

In the illustrated embodiment, the semiconductor die 104b is bonded to the semiconductor die 104a via a dielectric layer 122 and one or more interconnect structures 112. As a specific example, the semiconductor die 104b can be bonded to the semiconductor die 104a using thermocompression bonding (TCB) and/or a hybrid bond. As a result, the semiconductor device 100 can include a bondline between the semiconductor die 104a and the semiconductor die 104b. The dielectric layer 122 can be a non-conductive film or a molded underfill. The interconnect structures 112 can include bond pads, solder balls, and the like. Additionally, or alternatively, the interconnect structures 112 can be used to communicably and/or electrically couple (a) the semiconductor die 104b to (b) the semiconductor die 104a and/or the dielectric layer 110. In other embodiments, the semiconductor die 104b can be bonded to the semiconductor die 104a using another suitable bonding technique and/or another suitable bond type (e.g., a fusion bond).

As shown, the stack 102 of the semiconductor dies 104 is positioned on or over the dielectric layer 110. More specifically, the first side 106 of the semiconductor die 104a can be attached to the dielectric layer 110. As described in greater detail below, the dielectric layer 110 can be a layer deposited on the semiconductor die 104a during manufacturing of the semiconductor device 100. Thus, in some embodiments, the semiconductor device 100 can lack a bondline between the semiconductor die 104a and the dielectric layer 110. The dielectric layer 110 can be formed of SiO2, such as a low temperature (LT) SiO2, or another suitable material. In embodiments in which the dielectric layer 110 is formed using SiO2, the SiO2 material may have a lower bonding energy in comparison to permanent bonding materials.

The dielectric layer 110 can include one or more interconnect structures 114 formed therein. The one or more interconnect structures 114 can include vias, traces, bond pads, under bump metallurgy, etc. In some embodiments, the interconnect structures 114 extend through the dielectric layer 110. In these and other embodiments, the interconnect structures 114 may form a redistribution layer (RDL). As shown, external contacts 116 (e.g., pillars) can be formed on one or more of the interconnect structures 114 at a side of the dielectric layer 110 opposite the semiconductor die 104a. The external contacts 116 can be used to communicably and/or electrically couple the semiconductor dies 104 to a host device, external circuitry, or a power supply. In some embodiments, such as embodiments in which the semiconductor device 100 does not implement redistribution layers within the dielectric layer 110, a pitch of the interconnect structures 114 and/or the external contacts 116 can correspond to a pitch of corresponding bond pads/electrical contacts on the semiconductor die 104a. In other embodiments, such as embodiments in which the semiconductor device 100 implements a redistribution layer within the dielectric layer 110, a pitch of the interconnect structures 114 and/or the external contacts 116 can be relaxed/larger than a pitch of corresponding bond pads/electrical contacts on the semiconductor die 104a, such as to match JEDEC standards. The interconnect structures 114 and/or the external contacts 116 can be formed of nickel, gold, copper, tungsten, or another suitable material.

The gapfill material 118 may be positioned over and/or about the stack 102 and/or the dielectric layer 110. In the illustrated embodiment, the gapfill material 118 is disposed about the sides of the semiconductor dies 104 and the dielectric layer 110. As such, the semiconductor die 104b can be exposed at the top of the semiconductor device 100. In other embodiments, the gapfill material 118 can encapsulate, cover, and/or extend over all or a portion of the semiconductor die 104b at the top of the semiconductor device 100 (e.g., such that the semiconductor dies 104 and the dielectric layer 110 are surrounded by the gapfill material 118 along three or more sides of the semiconductor device 100). The gapfill material 118 can be formed using SiO2 (e.g., LT SiO2), or another suitable material. In some embodiments, the gapfill material 118 and the dielectric layer 110 may be distinguishable from one another in the semiconductor device 100. For example, the gapfill material 118 may have a different thickness (e.g., a great thickness) than a thickness of the dielectric layer 110 measured in a direction extending generally from the external contacts 116 toward the semiconductor die 104b.

As shown in FIG. 1, the gapfill material 118 is disposed between (a) the molding compound 120 and (b) the semiconductor dies 104 and the dielectric layer 110. As such, in some embodiments, the gapfill material 118 can serve as a barrier layer (e.g., during manufacturing of the semiconductor device 100), preventing the molding compound 120 from reaching (a) the bond between the semiconductor die 104a and the dielectric layer 110 and/or (b) the bond between the semiconductor die 104a and the semiconductor die 104b.

The molding compound 120 may be disposed over and/or about the stack 102 of semiconductor dies 104 and the dielectric layer 110. In the illustrated embodiment, the molding compound 120 is disposed about the sides of the semiconductor dies 104 and/or does not extend over the semiconductor die 104b (representing a topmost semiconductor die of the stack 102). In other embodiments, the gapfill material 118 can encapsulate, cover, and/or extend over all or a portion of the semiconductor die 104b at the top of the semiconductor device 100 (e.g., such that the semiconductor dies 104 and the dielectric layer 110 are surrounded by the gapfill material 118 along three or more sides of the semiconductor device 100).

In some cases, the dielectric layer 110 may emulate an interface or logic die of a high-bandwidth memory device (HBM), which may allow the semiconductor device 100 to emulate a high-bandwidth memory (HBM) device without using an interface or logic die.

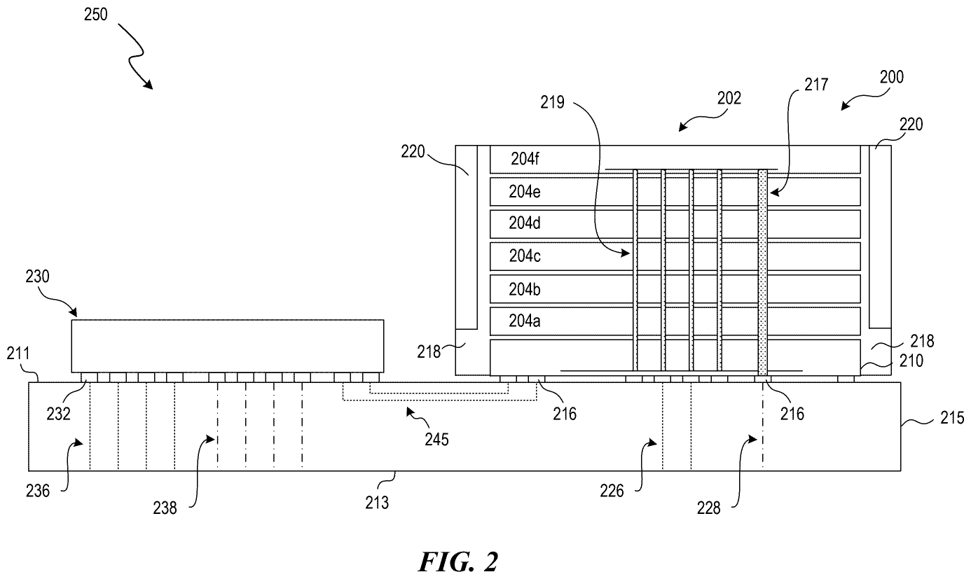

FIG. 2 is a partially schematic cross-sectional diagram of a system-in-package (SiP) device 250 configured in accordance with various embodiments of the present technology. As shown, the SiP device 250 includes an interposer 215 having a first surface 211 and a second surface 213 opposite the first surface 211. The interposer 215 can be a silicon interposer, an organic interposer, an inorganic interposer, and/or any other suitable base substrate. The SiP device 250 further includes a semiconductor device 200 and a host device 230 disposed on the first surface 211 of the interposer 215. The semiconductor device 200 is coupled to the interposer 215 via a plurality of contacts 216, and the host device 230 is coupled to the interposer 215 via a plurality of contacts 232. The contacts 216, 232 can be solder structures (e.g., solder balls), metal-metal bonds, and/or any other suitable conductive structures that mechanically and electrically couple the interposer 215 to the host device 230 and the semiconductor device 200.

The semiconductor device 200 can be generally similar to the semiconductor device 100 of FIG. 1 described in detail above. Accordingly, similar reference numbers are used across FIGS. 1 and 2 to denote identical or at least generally similar components, and a detailed description of the semiconductor device 200 is largely omitted here for the sake of brevity in light of the detailed description provided above. In the illustrated embodiment, the semiconductor device 200 includes a stack 202 of semiconductor dies 204 (identified individually in FIG. 2 as semiconductor dies 204a-204f) disposed on or over a dielectric layer 210 (e.g., an LT SiO2 layer), a gapfill material 218 disposed about the stack 202 of semiconductor dies 204 and the dielectric layer 210, and a molding compound 220 disposed about the stack 202.

The semiconductor dies 204a-204f are each communicably and/or electrically coupled to the dielectric layer 210 via one or more signal interconnect structures 219 (e.g., through silicon vias (TSVs) and/or other conductive structures) and one or more power interconnect structures 217 (e.g., TSVs and/or other conductive structures). The semiconductor dies 204a-204f can further be coupled to circuitry external the semiconductor device 200. For example, the semiconductor dies 204 can be coupled to the host device 230 via interconnect structures in the dielectric layer 210, the contacts 216, and communication channels 245 (sometimes referred to as a SiP bus) formed in the interposer 215. The communication channels 245 can include one or more route lines (two illustrated schematically in FIG. 2) formed into (or on) the interposer 215. Additionally, or alternatively, the semiconductor device 200 can be coupled to an external component (e.g., a PCB the interposer 215 is integrated with, an external controller, and/or the like), such as via interconnect structures in the dielectric layer 210, the contacts 216, signal interconnect structures 226 (e.g., TSVs and/or other conductive structures) formed in the interposer 215, and/or power interconnect structures 228 (e.g., TSVs and/or other conductive structures) formed in the interposer 215. In some embodiments, one or more signal interconnect structures 226 can be referred to as direct access interconnect structures, can be used to communicate signals (e.g., data, control signals, processing commands, and/or the like) between an external component and the dielectric layer 210, and/or can extend between the first surface 211 and the second surface 213 of the interposer 215. The power interconnect structures 228 can provide electrical power to the semiconductor device 200 from an external power source.

In some embodiments, the SiP device 250 can include an interface or logic die positioned on the first surface 211 of the interposer 215 between the interposer 215 and the semiconductor device 200 (e.g., between the interposer 215 and the dielectric layer 210). The interface or logic die can provide additional processing capabilities, memory control functions, or other logic operations to support the semiconductor device 200. The interface or logic die can allow the semiconductor device 200 to emulate a HBM device, for example, in embodiments in which the dielectric layer 210 is not configured to emulate an interface or logic die and/or is not configured to be used in lieu of an interface or logic die. The interface or logic die can be communicably and/or electrically coupled to the semiconductor device 200 through interconnect structures in the interface or logic die, contacts on the upper surface of the interface or logic die, and corresponding contacts on the lower surface of the semiconductor device 200, similar to contacts 216. Additionally, or alternatively, the interface or logic die can be coupled to the host device 230 via communication channels 245 formed in the interposer 215. The semiconductor device 200 can be communicably and/or electrically coupled to the host device 230 through the interface or logic die through interconnect structures in the interface or logic die and/or communication channels 245 formed in the interposer 215.

The host device 230 can include a variety of components, such as a processing unit (e.g., CPU/GPU/TCU), one or more registers, one or more cache memories, and/or a variety of other components. In some embodiments, the host device 230 can be coupled to an external component (e.g., a PCB the interposer 215 is integrated with, an external controller, and/or the like) via the contacts 232, signal interconnect structures 236 (e.g., TSVs and/or other conductive structures) formed in the interposer 215, and/or power interconnect structures 238 (e.g., TSVs and/or other conductive structures) formed in the interposer 215. The signal interconnect structures 236 and/or the power interconnect structures 238 can extend between the first surface 211 and the second surface 213 of the interposer 215. Additionally, or alternatively, the signal interconnect structures 236 can communicate signals (e.g., data, control signals, processing commands, and/or the like) between the external component and the host device 230. The power interconnect structures 238 can provide electrical power to the host device 230 from an external power source.

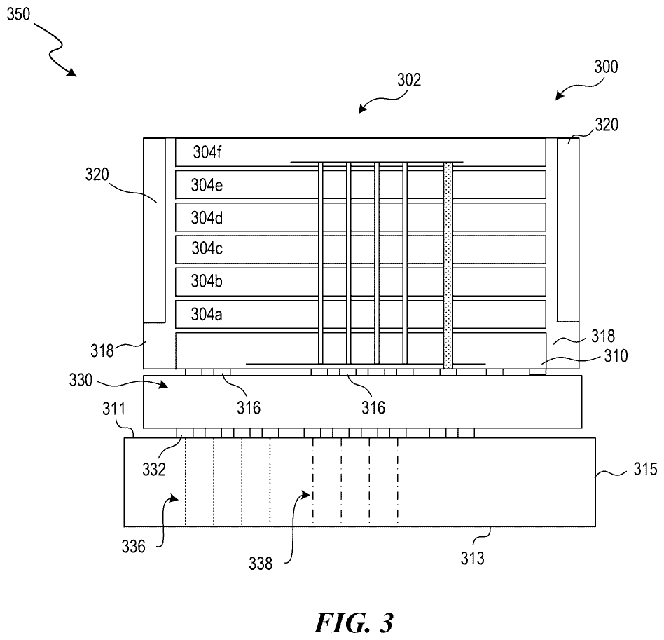

FIG. 3 illustrates a cross-sectional side view of another SiP device 350 configured in accordance with various embodiments of the present technology. The SiP device 350 is generally similar to the SiP device 250 of FIG. 2 described in detail above. Accordingly, similar reference numbers are used across FIGS. 2 and 3 to denote identical or at least generally similar components, and a detailed description of the SiP device 350 is largely omitted herein for the sake of brevity in light of the description of the SiP device 250 of FIG. 2 provided above.

As shown in FIG. 3, the SiP device 350 includes an interposer 315 (e.g., a silicon interposer, an organic interposer, an inorganic interposer, and/or any other suitable base substrate) having a first side 311 and a second side 313 opposite the first side 311. The SiP device 350 further includes a host device 330 and a semiconductor device 300 disposed on or over the first side 311 of the interposer 315. In contrast with the semiconductor device 200 of the SiP device 250 of FIG. 2, the semiconductor device 300 of the SiP device 350 of FIG. 3 is disposed on or over the host device 330. For example, the host device 330 can be coupled to the interposer 315 via a plurality of contacts 332, and the semiconductor device 300 is carried by the host device 330 and is coupled to the host device 330 via a plurality of contacts 316. The contacts 316, 332 can be solder structures (e.g., solder balls), metal-metal bonds, and/or any other suitable conductive structure.

The interposer 315 can include a plurality of signal interconnect structures 336 and a plurality of power interconnect structures 338. The signal interconnect structures 336 and/or the power interconnect structures 338 can include TSVs or other conductive structures, can extend between the first side 311 and the second side 313 of the interposer 315, and/or can be configured to transmit signals and/or power between an external component and the host device 330.

The semiconductor device 300 can be an example of the semiconductor device 100 of FIG. 1, the semiconductor device 200 of FIG. 2, or another semiconductor device configured in accordance with various embodiments of the present technology. Consistent with the discussion above, the semiconductor device 300 includes a plurality of semiconductor dies 304 (identified individually in FIG. 3 as semiconductor dies 304a-304f) arranged in a stack 302 and disposed on or over a dielectric layer 310 (e.g., formed of LT SiO2). The semiconductor device 300 can further include a molding compound 320, and gapfill material 318 disposed between (a) the molding compound 320 and (b) the stack 302 of semiconductor dies 304 and/or the dielectric layer 310.

In some embodiments, the SiP device 350 can include an interface or logic die positioned on the host device 330 and disposed between the host device 330 and the semiconductor device 300. The interface or logic die can be coupled to the host device 330 via a plurality of contacts similar to contacts 316. The interface or logic die can provide additional processing capabilities, memory control functions, or other logic operations to support the semiconductor device 300. The interface or logic die can allow the semiconductor device 300 to emulate an HBM device, for example, in embodiments in which the dielectric layer 310 is not configured to emulate an interface or logic die and/or is not configured to be used in lieu of an interface or logic die.

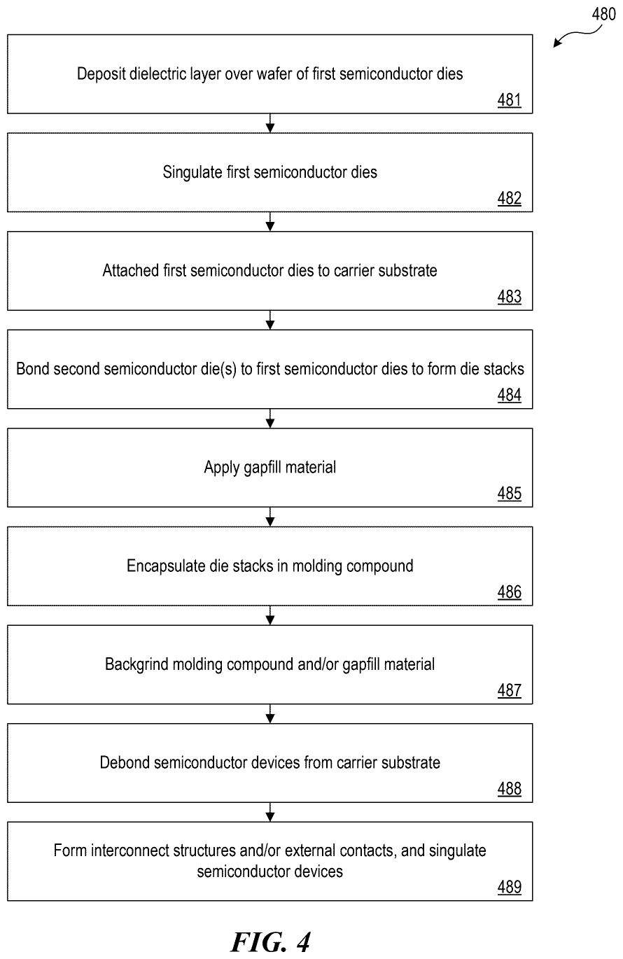

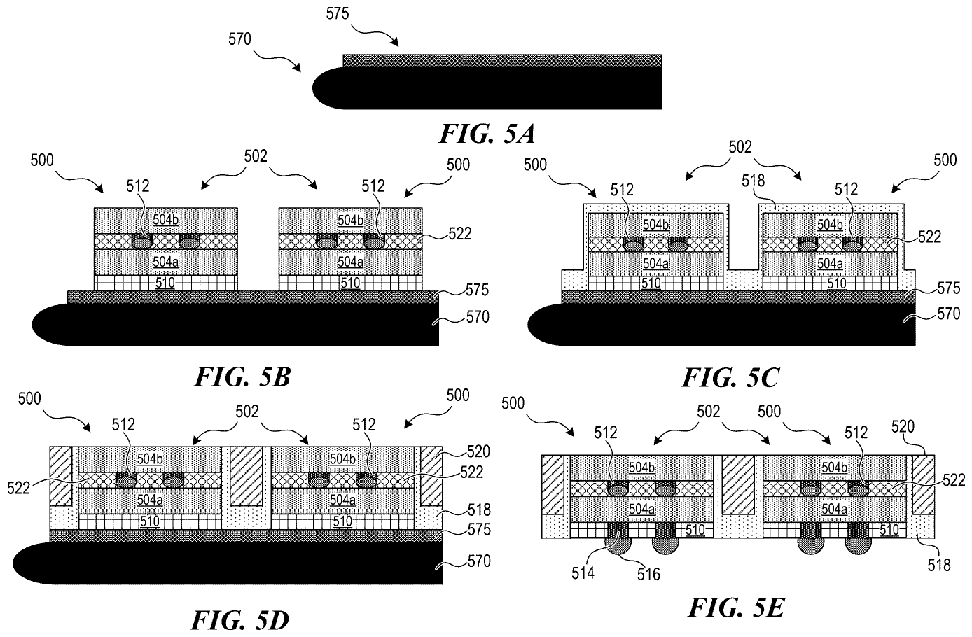

FIG. 4 is a flow diagram illustrating a method 480 of manufacturing a semiconductor device in accordance with various embodiments of the present technology. The semiconductor device can be the semiconductor device 100 of FIG. 1, the semiconductor device 200 of FIG. 2, the semiconductor device 300 of FIG. 3, or another semiconductor device configured in accordance with various embodiments of the present technology. The method 480 is illustrated as a series of steps 481-489. All or a subset of one or more of the steps 481-489 can be executed in accordance with the description above and/or with the description that follows. Indeed, several of the steps 481-489 are described in detail below with reference to FIGS. 5A-7. FIGS. 5A, 6, and 7 illustrate cross-sectional side views of temporary carrier substrates 570, 670, and 770, respectively, configured in accordance with various embodiments of the present technology. FIGS. 5B-5E illustrate cross-sectional side views of a semiconductor device 500 at various stages of manufacturing in accordance with various embodiments of the present technology.

At step 481, the method 400 begins by depositing a dielectric layer over a wafer of first semiconductor dies. The dielectric layer can be a layer of SiO2 (e.g., LT SiO2) or another suitable material. The first semiconductor dies can be memory dies, such as DRAM dies. The first semiconductor dies can be configured to serve as bottommost semiconductor dies in stacks of semiconductor dies.

At step 482, the method 400 continues by singulating the first semiconductor dies. Singulating the first semiconductor dies can include dicing the wafer, such as using a saw, a laser, or another suitable method. Singulating the first semiconductor dies can include separating the wafer into individual first semiconductor dies, each with a portion of the dielectric layer deposited thereon.

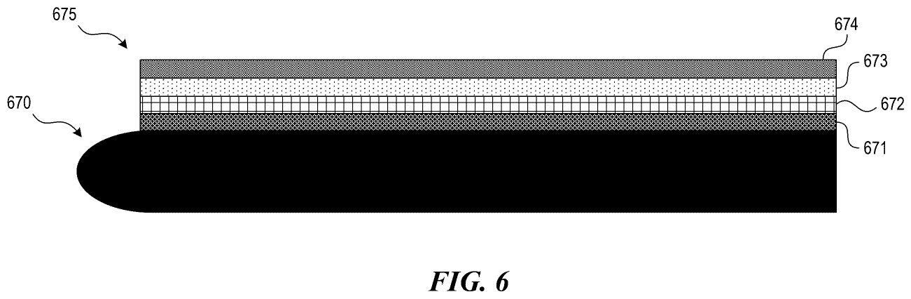

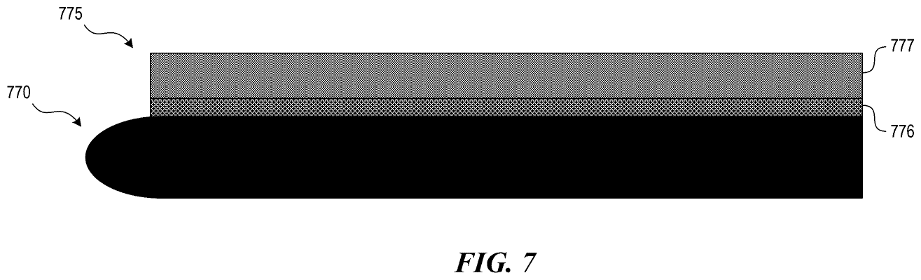

At step 483, the method 400 continues by attaching the first semiconductor dies to a carrier substrate. The carrier substrate can be a temporary carrier substrate, such as formed of silicon or glass. The carrier substrate can include a temporary layer disposed on or over the carrier substrate. For example, referring to FIG. 5A, the carrier substrate 570 can include a temporary layer 575 disposed thereon. In some embodiments, the temporary layer 575 can be formed from a plurality of layers. Two examples are shown in FIGS. 6 and 7.

In the example illustrated in FIG. 6, a temporary layer 675 is disposed on the carrier substrate 670. The carrier substrate 670 can be formed of silicon, glass, or another suitable material. As shown, the temporary layer 675 includes a plurality of layers. More specifically, the temporary layer 675 can include an ablation layer 671 that is usable to debond structures from the carrier substrate 670, as described in greater detail below. The temporary layer 675 can further include a dielectric layer 672, a shielding layer 673, and a bonding layer 674. The shielding layer 673 can be used to shield the bonding layer 674 and/or structures attached to the bonding layer 674 from radiation emitted, for example, using an infrared laser through the carrier substrate 670 and onto the ablation layer 671 to ablate the dielectric layer 672 and debond the temporary layer 675 from the carrier substrate 670. Such a debonding process is commonly referred to as nano cleaving (e.g., EVG nano cleaving) and/or dielectric debonding.

In the example illustrated in FIG. 7, a temporary layer 775 is disposed on the carrier substrate 770. The carrier substrate 770 can be formed of glass, silicon, or another suitable material. As shown, the temporary layer 775 includes a plurality of layers. More specifically, the temporary layer 775 includes (i) an ablation layer 776 that is usable to debond structures from the carrier substrate 770 and (ii) a bonding layer 777. The bonding layer 777 can be a high-temperature adhesive in some embodiments. In embodiments in which the carrier substrate 770 is formed of glass, the temporary layer 775 can be used to debond structures from the carrier substrate 770 using pulses of light. For example, the ablation layer 776 can be a light-absorbing layer. Continuing with this example, pulses of light can be emitted such that they propagate through the carrier substrate 770 and are absorbed by the ablation layer 776. As the ablation layer 776 absorbs the pulses of light, the ablation layer 776 can heat up and ablate the bonding layer 777, thereby enabling debonding of structures from the carrier substrate 770. Such a debonding process is commonly referred to as photonic debonding.

Referring again to step 483 of the method 400 of FIG. 4, attaching the first semiconductor dies to the carrier substrate can include attaching a side of the dielectric layer opposite the first semiconductor dies to the carrier substrate, such as using a die attach and/or a fusion bond (e.g., an oxide-to-oxide bond and/or a chip-to-wafer fusion bond). Thus, attaching the first semiconductor dies to the carrier substrate can include fusion bonding the first semiconductor dies to the carrier substrate using chip-to-wafer fusion bonds formed between the dielectric layer and a temporary layer disposed on the carrier substrate. Referring to FIG. 5B for the sake of clarity and example, the carrier substrate 570 from FIG. 5A and two singulated first semiconductor dies 504a are shown, each of the first semiconductor dies 504a having a dielectric layer 510 disposed thereon. Each of the first semiconductor dies 504a can be attached to the carrier substrate 570 of FIG. 5A via the temporary layer 575 disposed on the carrier substrate 570. More specifically, each of the first semiconductor dies 504a can be attached to the carrier substrate 570 at a side of the dielectric layer 510 opposite the first semiconductor dies 504a, such as using a fusion bond formed between the dielectric layer 540 and the temporary layer 575.

At step 484, the method 400 continues by bonding one or more second semiconductor dies to each of the first semiconductor dies to form die stacks. Bonding the one or more second semiconductor dies to each of the first semiconductor dies can include bonding the one or more second semiconductor dies to each of the first semiconductor dies at a side of the first semiconductor dies opposite the dielectric layers, such as using thermocompression bonding and/or hybrid bonds (e.g., chip-to-chip thermocompression bonding and/or chip-to-chip hybrid bonds).

Referring again to FIG. 5B for the sake of clarity and example, a second semiconductor die 504b can be bonded to each of the first semiconductor dies 504a on a side of the first semiconductor dies 504a opposite the dielectric layers 510 to form two die stacks 502. In the illustrated embodiment, the second semiconductor dies 504b are bonded to corresponding first semiconductor dies 504a via a dielectric layer 522 (e.g., a non-conductive film or a molded underfill) and interconnect structures 512 (e.g., bond pads, solder balls, and the like), such as using thermocompression bonding and/or a hybrid bond (e.g., a chip-to-chip hybrid bond).

At step 485, the method 400 continues by applying gapfill material. As discussed above, the gapfill material can be formed of SiO2 or another suitable material. Applying the gapfill material can include applying gapfill material to at least partially fill in gaps or spaces between adjacent die stacks/semiconductor devices arranged on the carrier substrate. In some embodiments, applying the gapfill material can include applying the gapfill material such that (i) an interface between the dielectric material and a corresponding first semiconductor die is covered or surrounded and/or (ii) the bond between the dielectric material and the temporary layer on the carrier substrate is covered or surrounded. For example, applying the gapfill material can include applying the gapfill material such that the gapfill material extends from (i) a position proximate the bond between the dielectric layer and the temporary layer to (ii) at least a height up each of the die stacks such that the interface between the dielectric material and the corresponding first semiconductor die of each of the die stacks is covered or surrounded. This can ensure that when molding compound is used to encapsulate the die stacks of the semiconductor devices at step 486 of the method 400 (described below), the gapfill material can act as a barrier, preventing the molding compound from reaching (i) the interfaces between the dielectric layer and the corresponding first semiconductor dies and (ii) the bond between the dielectric layer and the temporary layer. In these and other embodiments, applying the gapfill material can include encapsulating the die stacks such that the gapfill material is disposed along an entire height of each die stack and/or extends over or covers a top surface of the topmost semiconductor die in each die stack.

Referring to FIG. 5C for the sake of clarity and example, a gapfill material 518 is used to fill in gaps between adjacent die stacks 502 of adjacent semiconductor devices 500. In the illustrated embodiment, the gapfill material is deposited in the gaps such that the gapfill material extends at least to a point along the heights of each of the die stacks 502 to where (i) the interface between the dielectric layers 510 and the corresponding first semiconductor dies 504a and (ii) the bond between the dielectric layers 510 and the temporary layer 575 on the carrier substrate 570, are covered or surrounded. The gapfill material 518 can have a height (measured in a direction extending generally from temporary layer 575 toward the second semiconductor dies 504b) that is greater than a height of the dielectric layer 510, and/or the gapfill material 518 can extend from the temporary layer 575 to at least partway up the sides of the first semiconductor dies 504a in the die stacks 502. As shown, the gapfill material 518 encapsulates each of the die stacks 502, extending along the full heights of the die stacks 502 and across the top surfaces of each of the second semiconductor dies 504b (representing the topmost semiconductor dies) in each of the die stacks 502.

At step 486, the method 400 continues by encapsulating the die stacks in a molding compound. Encapsulating the die stacks can include disposing molding compound on or over the gapfill material and the dies stack, and/or between adjacent die stack of adjacent semiconductor devices on the carrier substrate.

At step 487, the method 400 continues by backgrinding the molding compound and/or the gapfill material. Backgrinding the molding compound and/or the gapfill material can include remove excess portions of the molding compound and/or the gapfill material disposed above at topmost semiconductor die of each die stack. In some embodiments, backgrinding the molding compound can include backgrinding the molding compound until gapfill material disposed on or over the die stacks is exposed and/or until a top surface of the topmost semiconductor die in the die stacks is exposed. In these and other embodiments, backgrinding the gapfill material can include backgrinding the gapfill material to remove gapfill material disposed on or over the die stacks and/or until a top surface of the topmost semiconductor die in the die stacks is exposed.

Referring to FIG. 5D for the sake of clarity and example, a molding compound 520 was previously disposed over the gapfill material 518 and each of the die stacks 502. In turn, excess molding compound 520 disposed above the second semiconductor dies 504b (representing the topmost semiconductor dies in each of the die stacks 502) has been removed via backgrinding. In addition, excess gapfill material 518 disposed on or over the second semiconductor dies 504b in FIG. 5C has been removed via backgrinding. In the illustrated embodiment, excess molding compound 520 and excess gapfill material 518 have been removed via backgrinding such that a top surface of the second semiconductor dies 504b of each of the die stacks 502 are exposed at the top of the semiconductor devices 500. As a result, the molding compound 520 and the gapfill material 518 are positioned at only locations that are laterally disposed with respect to die stacks 502, such as within gaps between adjacent die stacks 502. In other embodiments, the backgrinding process can conclude without removing all of the molding compound 520 and/or without removing all of the gapfill material 518 disposed on or over the second semiconductor dies 504b. In such embodiments, finalized semiconductor devices 500 can include molding compound 520 and/or gapfill material 518 disposed on or over at least a portion of the top surfaces of the second semiconductor dies 504b.

At step 488, the method 400 continues by debonding the semiconductor devices from the carrier substrate. Debonding the semiconductor devices can include separating the semiconductor devices from the carrier substrate at the temporary layer. For example, in embodiments in which the carrier substrate is formed of silicon, debonding the semiconductor devices can include debonding semiconductor devices by ablating one or more layers (e.g., an ablation layer and/or a dielectric layer) of the temporary layer through the carrier substrate and using a laser (e.g., an infrared laser), such as while shielding (e.g., using a shielding layer of the temporary layer) the semiconductor devices from radiation emitted by the laser. As another example, in embodiments in which the carrier substrate is formed of glass, debonding the semiconductor devices can include debonding the semiconductor devices by ablating one or more layers (e.g., a high-temperature adhesive layer) of the temporary layer, such as by emitting pulses of light through the carrier substrate and onto a light-absorbing ablation layer of the temporary layer. As still another example, debonding the semiconductor devices can include separating the semiconductor devices from the carrier substrate via mechanical debonding (e.g., pulling the semiconductor devices away from and/or apart from the carrier substrate).

At step 489, the method 400 continues by forming interconnect structures and/or external contacts, and singulating the semiconductor devices. Forming the interconnect structures can include forming vias, traces, bond pads, under bump metallurgy, redistribution layers, etc. within the dielectric layer attached to each of the first semiconductor dies. The interconnect structures can extend through the dielectric layer from a side of the dielectric layer opposite the first semiconductor die to a side of the dielectric layer attached to the first semiconductor die.

In the event the dielectric layer is a photoimageable material, forming the interconnect structures can include irradiating the dielectric layer (e.g., using ultraviolet (UV) light) through a mask, etching or otherwise removing exposed portions of the dielectric layer, and filling the resulting recesses/cavities/trenches with conductive material. In other embodiments, forming the interconnect structures can include disposing a layer of photoimageable material over the dielectric layer at a side of the dielectric layer opposite the first semiconductor dies, irradiating the photoimageable material (e.g., using UV light) through a mask, etching or otherwise removing exposed portions of the photoimageable material, filling the resulting recesses/cavities/trenches with conductive material, and removing remaining portions of the photoimageable material.

In some embodiments, forming the external contacts can include forming the external contacts as part of the process of forming the interconnect structures. In these and other embodiments, forming the external contacts can include forming the external contacts via pillar plating, such as using a pillar-last method. Singulating the semiconductor devices can include separating the semiconductor devices from one another, such as using a saw, a laser, or another suitable method.

Referring to FIG. 5E for the sake of clarity and example, the semiconductor devices 500 have been debonded from the carrier substrate 570 (FIG. 5D) at or proximate the interface between the dielectric layers 510 and the temporary layer 575 (FIG. 5D). In addition, interconnect structures 514 have been formed within the dielectric layers 510, and external contacts 516 have been formed on the interconnect structures 514. In the illustrated embodiment, the interconnect structures 514 are vias that extend all the way through the dielectric layers 510 from the external contacts 516 to the first semiconductor dies 504a, and the external contacts 516 are pillars. As discussed in greater detail above, the interconnect structures 514 and the external contacts can be used to communicably and/or electrically couple the first and/or second semiconductor dies 504a and/or 504b of the respective die stack 502 to external circuitry/components and/or power supplies. Although not shown in FIG. 5E, the two semiconductor devices 500 can be singulated, such as (i) using a saw, a laser, or another suitable method, and/or (ii) at a location positioned within the gap between the two semiconductor devices 500.

Although the steps 481-489 of the method 480 of FIG. 4 are discussed and illustrated in a particular order, the method 480 is not so limited. In other embodiments, all or a subset of one or more of the steps 481-489 of the method 480 can be performed in a different order. For example, although interconnect structures are formed in the dielectric layer at step 489 of the method 480 shown in FIG. 4, the interconnect structures can be formed in the dielectric layer at the wafer level and before singulating the first semiconductor dies at step 482. Thus, at least a portion of step 489 can be executed after step 481 and before step 482 in some embodiments. Moreover, a person of ordinary skill in the relevant art will recognize that the illustrated method 480 can be altered and still remain within these and other embodiments of the present technology. For example, all or a subset of one or more of the steps 481-489 of the method 480 illustrated in FIG. 4 can be omitted and/or repeated in some embodiments.

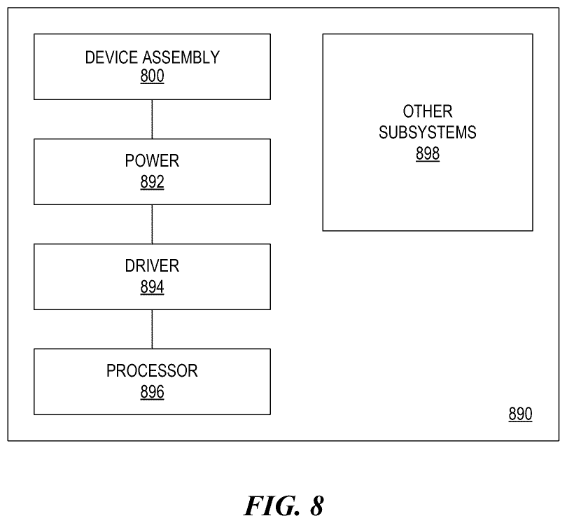

Any one of the semiconductor devices and semiconductor device assemblies described above with reference to FIGS. 1-7 can be incorporated into any of a myriad of larger and/or more complex systems, a representative example of which is system 890 shown schematically in FIG. 8. The system 890 can include a semiconductor device assembly 800 (e.g., similar to the semiconductor device 100, the semiconductor device 200, the semiconductor device 300, and/or the semiconductor device 500 described above with reference to FIGS. 1-3 and 5B-5E), a power source 892, a driver 894, a processor 896, and/or other subsystems or components 898. The semiconductor device assembly 800 can include features generally similar to those of the semiconductor devices described above with reference to FIGS. 1-7. The resulting system 890 can perform any of a wide variety of functions, such as memory storage, data processing, and/or other suitable functions. Accordingly, representative systems 890 can include, without limitation, hand-held devices (e.g., mobile phones, tablets, digital readers, and digital audio players), computers, vehicles, appliances, and other products. Components of the system 890 may be housed in a single unit or distributed over multiple, interconnected units (e.g., through a communications network). The components of the system 890 can also include remote devices and any of a wide variety of computer readable media.

### C. Conclusion

The above detailed descriptions of embodiments of the technology are not intended to be exhaustive or to limit the technology to the precise form disclosed above. Although specific embodiments of, and examples for, the technology are described above for illustrative purposes, various equivalent modifications are possible within the scope of the technology as those skilled in the relevant art will recognize. For example, although steps are presented in a given order above, alternative embodiments may perform steps in a different order. Furthermore, the various embodiments described herein may also be combined to provide further embodiments.

From the foregoing, it will be appreciated that specific embodiments of the technology have been described herein for purposes of illustration, but well-known structures and functions have not been shown or described in detail to avoid unnecessarily obscuring the description of the embodiments of the technology.

Where the context permits, singular or plural terms may also include the plural or singular term, respectively. In addition, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Moreover, as used herein, the phrases “based on,” “depends on,” “as a result of,” and “in response to” shall not be construed as a reference to a closed set of conditions. For example, an exemplary step that is described as “based on condition A” may be based on both condition A and condition B without departing from the scope of the present disclosure. In other words, as used herein, the phrase “based on” shall be construed in the same manner as the phrase “based at least in part on” or the phrase “based at least partially on.”

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments. Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

What is claimed is:

1. A semiconductor device, comprising:
a stack of semiconductor dies including a first semiconductor die and a second semiconductor die bonded to the first semiconductor die; and
a dielectric layer disposed on a side of the first semiconductor die opposite the second semiconductor die and including a plurality of interconnect structures formed therein,
wherein the semiconductor device lacks a bondline between the first semiconductor die and the dielectric layer.

2. The semiconductor device of claim 1, wherein the dielectric layer comprises low-temperature silicon dioxide.

3. The semiconductor device of claim 1, wherein one or more of the plurality of interconnect structures extend at least partway through the dielectric layer from a side of the dielectric layer opposite the first semiconductor die to a side of the dielectric layer attached to the first semiconductor die.

4. The semiconductor device of claim 3, further comprising a plurality of external contacts formed on the plurality of interconnect structures at the side of the dielectric layer opposite the first semiconductor die.

5. The semiconductor device of claim 1, wherein the second semiconductor die is bonded to the first semiconductor die via a thermocompression bond or a hybrid bond.

6. The semiconductor device of claim 1, further comprising:
a molding compound disposed about the stack of semiconductor dies; and
a gapfill material disposed between (i) the molding compound and (ii) an interface between the first semiconductor die and the dielectric layer.

7. The semiconductor device of claim 6, wherein the gapfill material comprises low-temperature silicon dioxide.

8. The semiconductor device of claim 6, wherein the gapfill material has a height that is greater than a height of the dielectric layer.

9. The semiconductor device of claim 6, wherein the gapfill material is disposed at a location laterally adjacent the dielectric layer and the first semiconductor die.

10. The semiconductor device of claim 1, wherein the first semiconductor die and the second semiconductor die comprise dynamic random-access memory (DRAM) dies.

11. A method of manufacturing a semiconductor device, the method comprising:
depositing a dielectric layer over a wafer of first semiconductor dies;
singulating the first semiconductor dies;
attaching a first semiconductor die of the first semiconductor dies to a carrier substrate;
stacking one or more second semiconductor dies over the first semiconductor die to form a die stack;
applying a gapfill material about the die stack; and
debonding the semiconductor device from the carrier substrate.

12. The method of claim 11, wherein depositing the dielectric layer includes depositing a dielectric layer formed of low-temperature silicon dioxide.

13. The method of claim 11, further comprising forming a plurality of interconnect structures in the dielectric layer.

14. The method of claim 11, wherein attaching the first semiconductor die to the carrier substrate comprises attaching a side of the dielectric layer opposite the first semiconductor die to the carrier substrate via a chip-to-wafer fusion bond formed between the side of the dielectric layer and a temporary layer disposed on the carrier substrate.

15. The method of claim 11, wherein stacking the one or more second semiconductor dies over the first semiconductor die includes bonding a second semiconductor die of the one or more second semiconductor dies to the first semiconductor die using a thermocompression bond or a hybrid bond.

16. The method of claim 11, wherein:
the method further comprises encapsulating the die stack in a molding compound;
applying the gapfill material and encapsulating the die stack in the molding compound include applying the gapfill material about the die stack and encapsulating the die stack in the molding compound such that the gapfill material is positioned between an interface between (a) the molding compound and (b) an interface between the dielectric layer and the first semiconductor die and/or a bond formed between the dielectric layer and the carrier substrate.

17. The method of claim 16, further comprising backgrinding excess portions of the molding compound and/or excess portions of the gapfill material.

18. A system-in-package (SiP) device, comprising:
a host device; and
a semiconductor device including:
a stack of semiconductor dies including (i) a first semiconductor die and (ii) a second semiconductor die bonded to the first semiconductor die,
a dielectric layer disposed on a side of the first semiconductor die opposite the second semiconductor die, wherein the SiP device lacks a bondline between the first semiconductor die and the dielectric layer,
interconnect structures formed in the dielectric layer, and
external contacts disposed at a side of the dielectric layer opposite the stack of semiconductor dies,
wherein the interconnect structures couple the first semiconductor die to the external contacts, and
wherein semiconductor dies of the stack are communicably coupled to the host device via one or more of the interconnect structures and one or more of the external contacts.

19. The system-in-package device of claim 18, wherein:
the semiconductor device further comprises—
a gapfill material disposed about the stack of semiconductor dies, and
a molding compound disposed about the gapfill material; and
the gapfill material comprises has a height that is greater than a height of the dielectric layer.

20. The system-in-package device of claim 18, wherein the dielectric layer comprises low-temperature silicon dioxide.
